(19) United States
(12) Patent Application Publication
(10) Pub. No.: US 2010/0039687 A1
(43) Pub. Date: Feb. 18, 2010

(54) Apparatus for Performing Confocal Endoscopy

(76) Inventors: Karthik Kumar, Austin, TX (US); Rebecca Richards-Kortum, Houston, TX (US); Xiaojing Zhang, Austin, TX (US)

Correspondence Address: DILLON & YUDELL LLP, 8911 NORTH CAPITAL OF TEXAS HWY, SUITE 2110, AUSTIN, TX, 78759, US

(21) Appl. No.: 12/193,501

(22) Filed: Aug. 18, 2008

(51) Int. Cl. G02B 26/08; B29D 11/00; H01L 21/30; H01L 21/461

(52) U.S. Cl. 359/201.1; 216/24; 438/455; 438/692

(57) ABSTRACT

A method for manufacturing a microscanner having a micro mirror is disclosed. Initially, a two-axis self-aligned vertical comb-drive microscanner is fabricated from a bonded silicon-on-insulator-silicon (SOI) silicon wafer. By depositing a thin film of aluminum on the surface, a SOI silicon wafer can provide about 90% reflectivity at 633 nm. A 2.5 μm misalignment tolerance can be achieved for the critical backside alignment step. As a result, confocal images with 1 μm resolution can be acquired using a microscanner having SOI silicon wafer mirrors.

### PRIORITY CLAIM

The present application claims priority under 35 U.S.C. §119(e)(1) to provisional application No. 60/965,417 filed on Aug. 20, 2007, the contents of which are incorporated herein by reference.

### BACKGROUND OF THE INVENTION

1. Technical Field

The present invention relates to microscanners in general, and, in particular, to a microscanner for performing confocal endoscopy.

2. Description of Related Art

Microscanners are essential components for the miniaturization of optical diagnostic equipments such as endoscopes. For example, silicon-based microscanners have been integrated into confocal and other instruments for providing images. However, the reflectivity of silicon mirrors having imaging wavelengths of 600-1550 nm is only about 30%. Such low reflectivity places limitations on minimal pinhole size and adversely affects depth resolution of confocal imaging equipments.

Consequently, it would be desirable to provide an improved microscanner for performing confocal imaging.

### SUMMARY OF THE INVENTION

In accordance with a preferred embodiment of the present invention, a two-axis self-aligned vertical comb-drive microscanner is fabricated from a bonded silicon-on-insulator (SOI) silicon wafer. By depositing a thin film of aluminum on the surface, a SOI silicon wafer can provide about 90% reflectivity at 633 nm. A 2.5 μm misalignment tolerance can be achieved for the critical backside alignment step. As a result, confocal images with 1 μm resolution can be achieved using a microscanner having SOI silicon wafer mirrors.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is an isomeric view of a microscanner, in accordance with a preferred embodiment of the present invention; and

FIGS. 2a-2h graphically illustrates a method for making the microscanner from FIG. 1, in accordance with a preferred embodiment of the present invention.

### DETAILED DESCRIPTION OF A PREFERRED EMBODIMENT

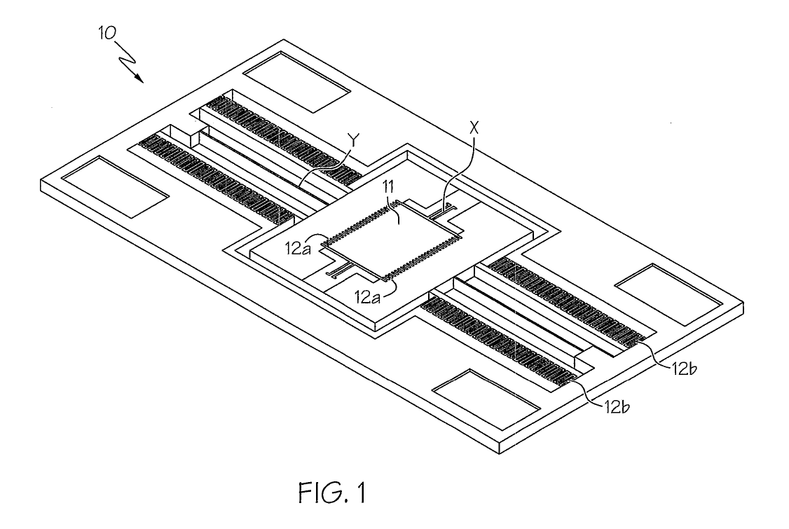

Referring now to the drawings and in particular to FIG. 1, there is depicted a diagram of a microscanner, in accordance with a preferred embodiment of the present invention. As shown, a microscanner 10 includes a micro mirror 11 controlled by a first bank of comb drive actuators 12a and a second bank of comb drive actuators 12b. Comb drive actuators 12a provide rotations of micro mirror 11 about an x-axis, and comb drive actuators 12b provide rotations of micro mirror 11 about a y-axis. The decoupled two-axis rotation can be achieved by mounting micro mirror 11 via a set of torsion rods in a frame with gimbals in an orthogonal direction.

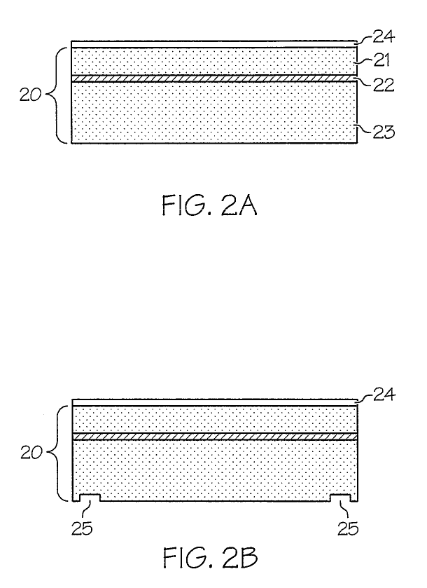

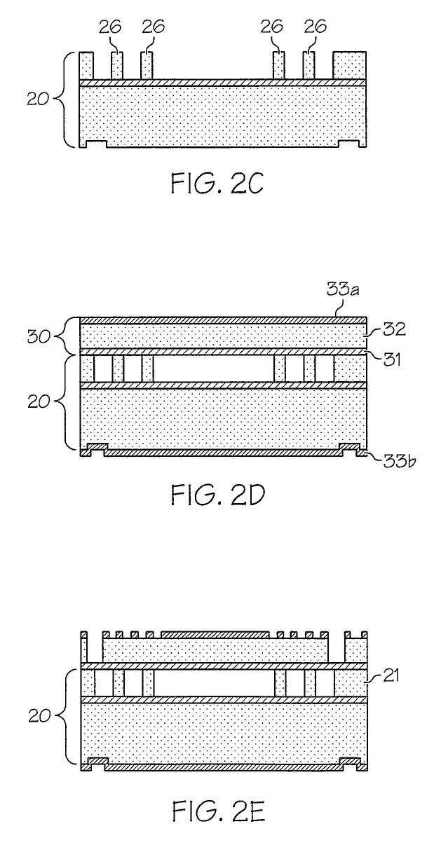

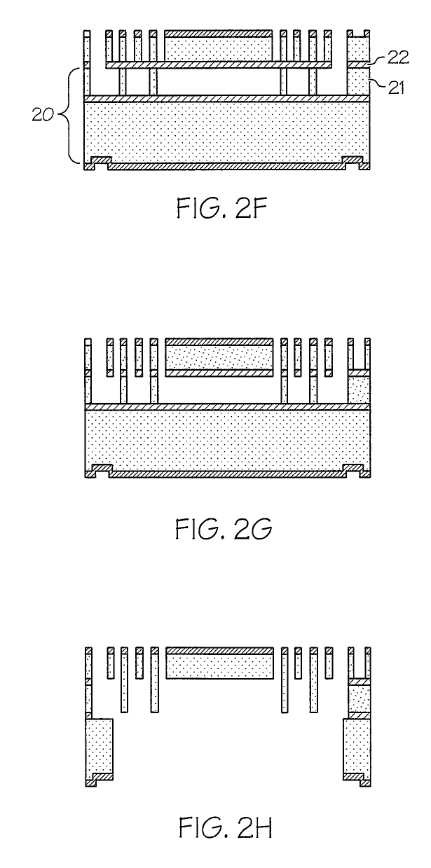

With reference now to FIGS. 2a-2h, there is depicted a high-level process flow diagram of a method for making microscanner 10 having a micro mirror, in accordance with a preferred embodiment of the present invention. The fabrication of microscanner 10 begins with the protection of the surface of a silicon-on-insulator (SOI) silicon wafer by thermal oxidation. For example, a silicon dioxide layer 24 can be formed on a 30 μm SOI silicon wafer 20, which includes a silicon layer 21, an oxide layer 22 and a substrate layer 23, via wet oxidation at 1,100° C., as shown in FIG. 2a. After the frontside of SOI silicon wafer 20 has been protected by silicon dioxide layer 24, alignment marks 25 are dry etched into the backside of SOI silicon wafer 20, as depicted in FIG. 2b. Silicon dioxide layer 24 is then removed from the frontside of SOI silicon wafer 20 via buffer oxide etch, and coarse features 26 of mirror frame and outer stator combs, which are aligned to alignment marks 25 on the backside of SOI silicon wafer 20, are subsequently etched into silicon layer 21 via a Deep Reactive Ion Etching (DRIE) process.

A silicon wafer 30 having a −4800 Å thick thermal oxide 31 is then fusion bonded on top of SOI silicon wafer 20, as depicted in FIG. 2d. The above-mentioned initial protection of SOI silicon wafer 20 by silicon dioxide layer 24 is important for achieving a high yield in the fusion bonding process. After the fusion bonding, silicon wafer 30 is ground to a thickness of approximately 20 μm and polished in order to yield a smooth surface to serve as an optical interface. A micro mirror will be fabricated on a layer 32 of silicon wafer 30. Low-temperature oxide (LTO) layers 33a, 33b of approximately 1 μm are deposited on silicon wafer 30 and SOI silicon wafer 20, respectively, via low-pressure chemical vapor deposition, as depicted in FIG. 2d.

DRIE is utilized to expose front alignment marks, oxide with bond pads and exact microscanner features, as shown in FIG. 2e. DRIE is again utilized to etch silicon layer 21. as depicted in FIG. 2f. The exact features of the stator and rotor combs of the microscanner are then defined by etching through oxide layer 22, as shown in FIG. 2g.

After the self-alignment step, all features of the microscanner are defined, and DRIE process is used on the backside of SOI silicon wafer 20 to release the microscanner, as shown in FIG. 2h.

The device wafer is bonded to a handle wafer by photoresist, and backside DRIE of the outline of the microscanner is performed using the alignment marks previously etched into the backside of the device wafer. The device is soaked in acetone for approximately 12 hours to release device wafer from the handle wafer. Dry oxide etch is performed on the frontside and backside to remove exposed oxide from the mirror surfaces.

An E-beam evaporation is used to coat a thin film (500-1000 Å) of aluminum on the mirror surface to improve reflectivity. The non-conformal nature of deposition combined with large step height can be taken advantage of to deposit metal on the mirror surface without electrically connecting the different layers. Preferably, micro mirrors are fabricated with dimensions of 500 μm×700 μm in order to facilitate illumination at 45° incidence by a 500 μm diameter laser beam, which allows for uncomplicated optical paths and easy integration into an imaging system.

As has been described, the present invention provides a microscanner for performing single-fiber confocal endoscopy.

While the invention has been particularly shown and described with reference to a preferred embodiment, it will be understood by those skilled in the art that various changes in form and detail may be made therein without departing from the spirit and scope of the invention.

What is claimed is:

1. A method for manufacturing a microscanner having a micro mirror, said method comprising:
depositing an oxide layer on a silicon-on-insulator (SOI) silicon wafer;
dry etching alignment marks into a backside of said SOI silicon wafer;
etching coarse features of mirror frame and outer stator combs into a device layer of said SOI silicon wafer after said oxide layer has been removed from said frontside of said SOI silicon wafer, wherein said mirror frame and outer stator combs are aligned with said alignment marks on said backside of said SOI silicon wafer;
fusion bonding a silicon wafer having a thermal oxide on top of said SOI silicon wafer;
grounding and polishing said silicon wafer to yield a smooth surface to serve as a mirror;
depositing a low temperature oxide (LTO) layer on said silicon wafer;
etching said LTO layer to define bond pads, stator and rotor combs of a microscanner; and
coating said mirror of said microscanner with a thin film to improve reflectivity of said mirror.

2. The method of claim 1, wherein said etchings are performed by a Deep Reactive Ion Etching (DRIE) process.

3. The method of claim 1, wherein said thermal oxide is grown on a different <100> silicon wafer.

4. The method of claim 1, wherein said coating is performed by an evaporation process.

5. The method of claim 1, wherein said thin film is aluminum.

6. A microscanner comprising:
a micro mirror fabricated on a silicon-on-insulator (SOI) silicon wafer, wherein said micro mirror is coated with a thin film;
a first bank of comb drive actuators for controlling rotations of said micro mirror about an x-axis; and
a second bank of comb drive actuators for controlling rotations of said micro mirror about a y-axis.

7. The microscanner of claim 6, wherein said thin film is aluminum.

8. The microscanner of claim 6, wherein said micro mirror is mounted via a set of torsion rods in a frame with gimbals in an orthogonal direction.
